(19) United States
(12) Patent Application Publication
(10) Pub. No.: US 2005/0214678 A1
(43) Pub. Date: Sep. 29, 2005

(54) Light-sensitive lithographic printing plate

(75) Inventor: Akira Nagashima, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/089,487

(22) Filed: Mar. 25, 2005

(30) Foreign Application Priority Data
Mar. 26, 2004 (JP) 2004-091362

(51) Int. Cl. G03F 7/00

(52) U.S. Cl. 430/270.1

(57) ABSTRACT

A light-sensitive lithographic printing plate comprises a hydrophilic substrate provided thereon with an infrared light-sensitive layer which comprises (A) an acetal polymer having a specific structure; (B) a polymeric compound carrying, on the side chains, fluorinated aliphatic groups in which the fluorinated aliphatic groups are those derived from fluorinated aliphatic compounds prepared by the telomerization or oligomerization; and (C) a light-heat conversion substance. The light-sensitive lithographic printing plate is excellent in the both printing durability and the developing latitude.

### BACKGROUND OF INVENTION

The present invention relates to a light-sensitive lithographic printing plate and more specifically to a positive-working light-sensitive lithographic printing plate for use in a so-called direct plate-making method, which permits the direct preparation of a lithographic printing plate based on digital data outputted from, for instance, a computer and recorded thereon with an infrared laser.

The laser technology has rapidly been developed recently and this make it easy to obtain high power and miniaturized solid state and/or semiconductor laser devices which can emit light rays having wavelengths falling within the near infrared to infrared region. These lasers are quite useful as light sources in the direct plate-making method in which a lithographic printing plate is directly prepared based on digital data outputted from, for instance, a computer.

As an image-recording material which makes use of a laser capable of emitting light rays having a wavelength falling within the near infrared to infrared region, there has been proposed a positive-working light-sensitive lithographic printing plate which comprises a binder such as a cresol resin, a substance which can absorb light rays and in turn generate heat and a heat-decomposable substance such as a quinone diazide compound which can substantially reduce the solubility of the foregoing binder when it is not decomposed (see, for instance, Japanese Un-Examined Patent Publication (hereunder referred to as “J.P. KOKAI”) Hei 7-285275). This image-recording material is a heat-mode light-sensitive lithographic printing plate which can absorb light rays and generate heat on its exposed area due to the presence of such a heat-generating substance when it is irradiated with an infrared laser beam. Then, the imagewise exposed material is developed with an alkaline aqueous solution to thus remove only the exposed area on the material through dissolution and to expose the surface of the substrate. In this case, the lipophilic recording layer (light-sensitive layer) remains on the unexposed area (image area) on the material and thus serves as an ink-receiving area, while the hydrophilic substrate surface is exposed on the light-exposed area (non-image area) and this area serves to retain water and acts as ink-repellent layer.

Moreover, it has also been reported that the rate of remaining film on the unexposed area can be improved by the addition of an organic acid in case of a positive-working light-sensitive composition containing a substance capable of converting light rays into heat (light-heat conversion substance) and an alkali-soluble resin (see, J.P. KOKAI Hei 10-282643).

Further, there has likewise been proposed a positive-working light-sensitive composition which comprises a light-heat conversion substance, a novolak resin and an acrylic resin in a specific ratio by weight and which has a high light-sensitivity and an improved rate of remaining film on the unexposed area (see J.P. KOKAI 2001-324808).

In addition, there has also been proposed a light-sensitive lithographic printing plate having excellent printing durability obtained using a positive-working light-sensitive composition which comprises a light-heat conversion substance and a specific acetal polymer (see J. P. Tokuhyo 2003-53058).

However, the foregoing conventional techniques have still been insufficient in the processability when the activity of a developer is changed (developing latitude) and the printing durability of the lithographic printing plate finally obtained. Therefore, it has still been desired for the development of a technique which permits the elimination of the foregoing drawbacks associated with the conventional techniques.

### SUMMARY OF THE INVENTION

Accordingly, it is an object of the present invention to provide a light-sensitive lithographic printing plate which permits the direct preparation of a lithographic printing plate based on digital data outputted from, for instance, a computer and recorded on the light-sensitive layer of the plate using an infrared-scanning exposure technique, and which can ensure a high developing latitude and provide a lithographic printing plate having excellent printing durability.

The inventors of this invention have conducted various studies to eliminate the drawbacks of the foregoing conventional technique, have found that it is quite effective to use a combination of an acetal polymer having a specific structure; a specific polymeric compound carrying, on the side chains, fluorinated aliphatic groups; and a light-heat conversion substance for the improvement of the developing latitude of the resulting light-sensitive material and for the preparation of a lithographic printing plate having a high printing durability and have thus completed the present invention.

According to the present invention, there is provided a light-sensitive lithographic printing plate comprising a hydrophilic substrate provided thereon with a layer sensitive to infrared light rays (hereunder referred to as “infrared light-sensitive layer”) which comprises (A) a polymer represented by the following general formula (I); (B) a polymeric compound carrying, on the side chains, fluorinated aliphatic groups in which the fluorinated aliphatic groups are those derived from fluorinated aliphatic compounds prepared by the telomerization or oligomerization; and (C) a light-heat conversion substance.

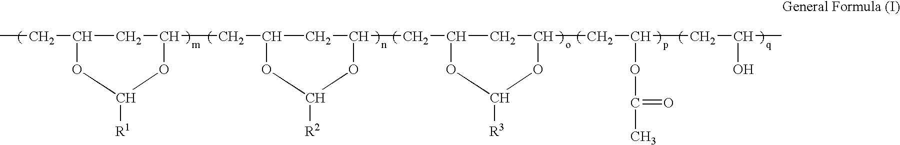

In Formula (I), R¹ represents a group: —CₙH₂ₙ₊₁ (wherein n ranges from 1 to 12); R² represents a group represented by the following structural formula.

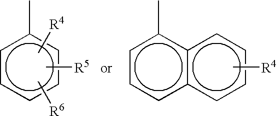

(In the foregoing formula, R⁴=—OH; R⁵=—H, —OH, —OCH₃, —Br, or —O—CH₂—C≡CH; R⁶=—H, —Br, or —NO₂); R³ represents —(CH₂)ₐ—COOH, —C≡CH or the following group:

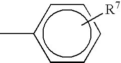

(In the formula, R⁷=—COOH, —(CH₂)ₐ—COOH, or —O—(CH₂)ₐ—COOH); a represents an integer ranging from 1 to 6; m=5 to 40 mole%, n =10 to 60 mole %, o=0 to 20 mole %, p=1 to 10 mole %, and q=5 to 50 mole %.

According to another aspect of the present invention, there is also provided a light-sensitive lithographic printing plate comprising the infrared light-sensitive layer of the foregoing light-sensitive lithographic printing plate which further comprises (D) an organic acid and/or a cyclic acid anhydride incorporated therein.

The present invention thus permits the direct preparation of a lithographic printing plate based on digital data outputted from, for instance, a computer and recorded using an infrared-scanning exposure technique, and the present invention can in turn ensure a high developing latitude and provide a lithographic printing plate having excellent printing durability.

### BEST MODE FOR CARRYING OUT THE INVENTION

The light-sensitive lithographic printing plate of the present invention is characterized in that it comprises a substrate and an infrared light-sensitive layer (hereunder simply referred to as “light-sensitive layer”). These constituents will hereunder be described in more detail.

[Light-Sensitive Layer]

The light-sensitive layer used in the present invention will hereunder be described in more detail. First, the light-sensitive layer used herein comprises acetal polymer represented by the general formula (I) as the component (A):

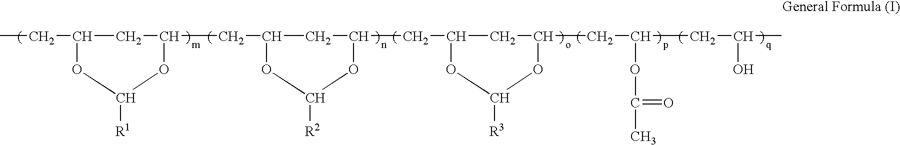

In Formula (I), R¹ represents a group: —CₙH₂ₙ₊₁ (wherein n ranges from 1 to 12); R² represents a group represented by the following structural formula:

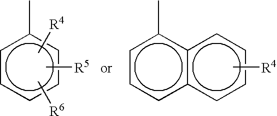

(In the foregoing formula, R⁴=—OH; R⁵=—H, —OH, —OCH₃, —Br, or —O—CH₂—C≡CH; R⁶=—H, —Br, or —NOₛ); R³ represents —(CH₂)ₐ—COOH, —C≡CH or the following group:

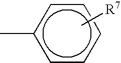

(In the formula, R⁷=—COOH, —(CH₂)ₐ—COOH, or —O—(CH₂)ₐ—COOH); a represents an integer ranging from 1 to 6; m=5 to 40 mole %, n=10 to 60 mole %, o=0 to 20 mole %, p=1 to 10 mole %, and q=5 to 50 mole %.

The acetal polymer used in the invention and represented by Formula (I) has a weight average molecular weight ranging from about 5,000 to 300,000.

The acetal polymer component (A) is incorporated into the light-sensitive layer in an amount ranging from 10 to 99% by weight and preferably 40 to 95% by weight on the basis of the total solid content of the layer.

As will be clear from the foregoing structural formula, the acetal polymer component used in the invention may comprise, as a repeating unit, a tetramer (in case where o is 0) comprising vinyl acetate moieties and vinyl alcohol moieties, as well as first and second cyclic acetal groups; or a pentamer (in case where o is not 0) comprising vinyl alcohol moieties, vinyl acetate moieties, and first, second and third cyclic acetal groups.

The polyvinyl acetal polymer represented by Formula (I) may be derived from, for instance, a vinyl alcohol-vinyl acetate copolymer. The starting material used for the preparation of the polymer according to the present invention may comprise a vinyl acetate-vinyl alcohol copolymer containing vinyl alcohol units in an amount of at least about 80% and having an average molecular weight ranging from about 2,000 to 120,000 and preferably about 8,000 to 50,000. Examples of polyvinyl alcohols appropriately used herein those having molecular weights falling within the range specified above and commercially available from Clariant GmbH under the trade marks of, for instance, MOWIOL 3-83, MOWIOL 3-98 and MOWIOL 4-88; those commercially available from AIR PRODUCTS CORP. under the trade marks of, for instance, AIRVOL 103, 203 and 502; and those commercially available from ALDRICH Company and other suppliers.

Examples of aldehydes useful and suitable for the preparation of the first cyclic acetal group (the acetal group containing the group R¹) of the acetal polymer are acetaldehyde, propionaldehyde, n-butyl aldehyde, n-valeraldehyde, n-caproaldehyde, n-heptaldehyde, isobutyl aldehyde, isovaleraldehyde and mixture thereof.

Examples of aldehydes useful and suitable for the preparation of the second cyclic acetal group (the acetal group containing the group R²) of the acetal polymer are 2-hydroxy-benzaldehyde, 3-hydroxy-benzaldehyde, 4-hydroxy-benzaldehyde, 2-hydroxy-1-naphthaldehyde, 2,4-dihydroxy-benzaldehyde, 3,5-dibromo-4-hydroxy-benzaldehyde, 4-oxypropynyl-3-hydroxy-benzaldehyde, vanillin, isovanillin, cinnamaldehyde and mixture thereof.

Examples of aldehydes useful and suitable for the preparation of the third cyclic acetal group (the acetal group containing the group R³) of the acetal polymer are glyoxylic acid, 2-formylphenoxy acetic acid, 3-methoxy-4-formylphenoxy acetic acid, propargyl aldehyde and mixture thereof.

The polyvinyl alcohol can be converted into an acetal according to any known method and examples of such methods are those disclosed in, for instance, U.S. Pat. Nos. 4,665,124, 4,940,646, 5,169,898, 5,700,619, and 792,823; and Japanese Patent No. 09328519.

The polymeric compound carrying, on the side chains, fluorinated aliphatic groups (hereunder also referred to as “fluorine atom-containing polymer”) as the component (B) used in the present invention are those derived from fluorinated aliphatic compounds prepared by the telomerization method (also referred to as “telomer method”) or oligomerization method (also referred to as “oligomer method”). Methods for the preparation of these fluorinated aliphatic compounds are disclosed in, for instance, “Synthesis and Functions of Fluorine Atom-Containing Compounds”, edited by ISHIKAWA Nobuo, published by CMC Company, 1987, pp. 117-118; and “Chemistry of Organic Fluorine Compounds II” (Monograph 187, Edited by Milos Hudlicky and Attila E. Pavlath, American Chemical Society, 1995, pp. 747-752. The telomerization technique is a method for the synthesis of a telomer by subjecting a fluorine atom-containing vinyl compound such as tetrafluoro-ethylene to radical polymerization using an alkyl halide having a high chain transfer coefficient such as an iodide as a telogen (an example will be given in the following Reaction Scheme 1).

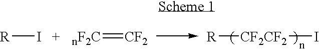

The resulting telomer having iodinated terminal is in general subjected to an appropriate chemical modification of the terminal, such as those described in the following Reaction Scheme 2 so that the telomer is thus converted into a fluorinated aliphatic compound. Further these compounds are, if necessary, converted into those having desired monomer structures and then used in the preparation of a desired fluorinated aliphatic group-containing polymer:

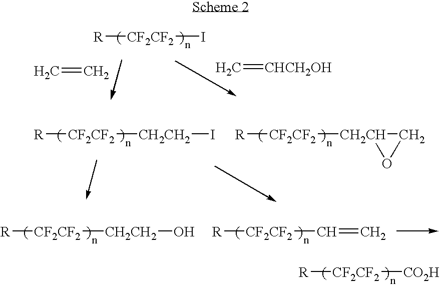

Specific examples of the compounds prepared by the foregoing telomer method and suitably used for forming the side chains of the polymeric compound carrying, on the side chains, fluorinated aliphatic groups according to the present invention are fluorine atom-containing chemicals available from DAIKIN Chemical and Industrial Product Distributing Co., Ltd. such as A-1110, A-1210, A-1310, A-1420, A-1620, A-1820, A-2020, A-1260, A-1460, A-1660, A-1860, A-1435, A-1635, A-1835, A-1473, A-1637, A-1837, A-1514, A-3420, A-3620, A-3820, A-4020, A-3260, A-3460, A-3660, A-3860, A-3637, A-3837, A-5210, A-5410, A-5610, A-5810, A-7110, A-7210, A-7310, A-9211, C-1100, C-1200, C-1300, C-1400, C-1500, C-1600, C-1700, C-1800, C-1900, C-2000, C-5200, C-5400, C-5600, C-5800, C-5208, C-5408, C-5608, C-6008, C-8200, C-8300, C-8500, C-9211, C-8208, C-8308, C-8508, C-9216, E-1430, E-1630, E-1830, E-2030, E-3430, E-3630, E-3830, E-4030, E-5244, E-5444, E-5644, E-5844, F-1420, F-1620, F-1820, F-2020, I-1200, I-1300, I-1400, I-1600, I-1700, I-1800, I-2000, I-1420, I-1620, I-1820, I-2020, I-3200, I-3400, I-3600, I-3800, I-4000, I-3620, I-3820, I-4020, I-5200, I-5400, I-5600, I-8208, I-8207, I-8407, I-8607, M-1110, M-1210, M-1420, M-1620, M-1820, M-2020, M-3420, M-3620, M-3820, M-4020, M-3433, M-3633, M-3833, M-4033, M-5210, M-5410, M-5610, M-5810, M-6010, M-7210, M-7310, R-1110, R-1210, R-1420, R-1620, R-1820, R-2020, R-1433, R-1633, R-1833, R-3420, R-3620, R-3820, R-4020, R-3433, R-5210, R-5410, R-5610, R-5810, R-6010, R-7210, R-7310, U-1310 and U-1710; and those manufactured by Nippon MECTRON Co., Ltd. such as CHEMINOX FA, FA-M, FAAC, FAAC-M, FAMAC and FAMAC-M and the structures of the principal components of these fluorine atom-containing chemical products are those represented by the following general formula TM-1 (in the formula, n is an integer ranging from 0 to 20):

| | | |
|---|---|---|
| 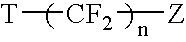 | [TM-1] | |
| —T | —Z | |
| —CF3 | —CH₂OH | —CH═CHCH₂OH |
| —CF₂CF₃ | —CH₂CH₂OH | —CH₂CHICH₂OH |
| —CF₂CF₂CF₃ | 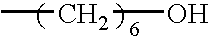 | —OCF₂(CF₃)CH₂OH |
| 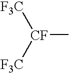 | —CO₂H —COCl | —I —Br |
| —CF₂CF₂H | 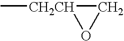 | CH₂CH₂I —CH₂I |
| | —CH═CH₂ | —CH₂NH₂ |
| | 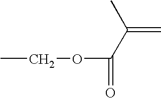 | 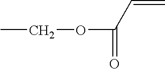 |
| | 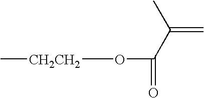 | 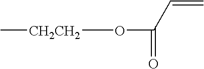 |

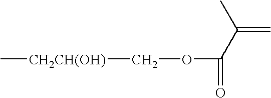

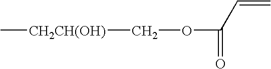

These fluorine atom-containing chemical products can easily be converted into a polymeric compound carrying, on the side chains, fluorinated aliphatic groups according to the method known to one of ordinary skill in the art. In the foregoing general formula TM-1, the compounds in which -Z represents a group listed below are particularly preferably used in the present invention since they have acryloyl or methacryloyl groups on the termini thereof and accordingly, they can easily be converted into the polymeric compound carrying, on the side chains, fluorinated aliphatic groups according to the present invention through the double bond polymerization.

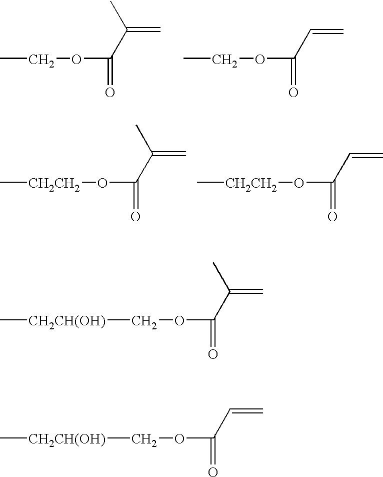

In addition, the polymeric compounds per se each carrying, on the side chains, fluorinated aliphatic groups preferably used in the present invention and prepared while making use of fluorine atom-containing chemical products obtained through the telomer method have already been commercially available under the general name of “perfluoroalkyl-containing oligomer” and these commercially available ones may preferably be used herein. Examples of such chemical products are those manufactured and sold by Dianippon Ink and Chemicals, Inc. under the trade names of MEGAFAC F-178K, MEGAFAC F-470, MEGAFAC F-473, MEGAFAC F-475, MEGAFAC-F-476, MEGAFAC F-472 and MEGAFAC R-08; and those prepared by Asahi Glass Co., Ltd. under the trade names of SURFLON S-381, S-383, S-393, S-101 and S-105. Among these chemical products, particularly preferred are MEGAFAC F-178K (hereunder referred to as P-1), MEGAFAC F-470 (hereunder referred to as P-2), MEGAFAC F-473 (hereunder referred to as P-3), MEGAFAC F-475 (hereunder referred to as P-4), MEGAFAC F-476 (hereunder referred to as P-5) and MEGAFAC F-472 (hereunder referred to as P-6) since they are excellent in the quality balance between the hydrophobicity of the surface of the image area and the removability of the non-image area through development and the ability of hardly forming developing scum.

The fluorinated aliphatic compounds prepared according to the oligomerization method are also preferably used in the present invention. The oligomerization technique is a method (see the following Reaction Scheme 3) for the preparation of an oligomer by cationic polymerization of tetrafluoroethylene using potassium fluoride or cesium fluoride as a catalyst in a polar solvent such as diglyme (diethylene glycol dimethyl ether) and the compounds may be converted into desired polymeric compounds carrying, on the side chains, fluorinated aliphatic groups, through appropriate chemical modification while making use of the reactive groups (unsaturated bonds) present on the resulting oligomer obtained through the polymerization as in the case of the foregoing telomerization method:

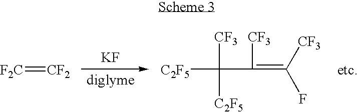

Representative methods for preparing the fluorinated aliphatic compounds other than the foregoing telomerization and oligomerization methods are, for instance, the electrolytic fluorination method and the indirect fluorination method. In particular, commercially quite effective ones are perfluoro-octyl sulfonic acid fluorides prepared according to the electrolytic fluorination method (Reaction Scheme 4) as well as fluorine atom-containing chemical products derived from the foregoing fluorides and these compounds have been preferably used. Contrary to this, the inventors of this invention have found that excellent results can be obtained by the use of fluorine atom-containing chemical products prepared by the telomerization and oligomerization methods in place of the foregoing ones prepared by the electrolytic fluorination method:

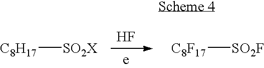

The following groups represented by the general formula (II) are preferred examples of fluorinated aliphatic group in the polymeric compounds of component (B) and the fluorinated aliphatic group is derived from the fluorinated aliphatic compound produced according to the telomerization and oligomerization methods.

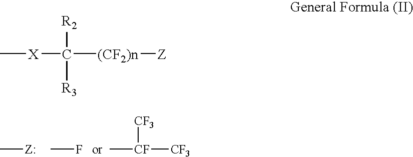

In the formula, each of R₂ and R₃ independently represents a hydrogen atom or an alkyl group having 1 to 4 carbon atoms; X represents a single bond or a divalent connecting group and is connected to the main chain of the polymer; m represents 0 or an integer of not less than 1; and n is an integer of not less than 1 and not more than 10.

Specific examples of the alkyl groups represented by R₂ and R₃ are methyl, ethyl, propyl, isopropyl, n-butyl, isobutyl and tert-butyl groups, but each of these substituents R₂ and R₃ is preferably a hydrogen atom or a methyl group and more preferably a hydrogen atom.

X represents a covalent bond or a divalent connecting group. X preferably represents —O—, —S—, —N(R₄)—, —CO—, —COO— or —CON(R₄)— and it is connected to the main chain of the polymer directly or through a divalent connecting group. In this respect, R₄ represents a hydrogen atom or a C1 to C4 alkyl group. Specific examples of such alkyl groups are methyl, ethyl, propyl, isopropyl, n-butyl, isobutyl and tert-butyl groups, but the substituent R₄ is preferably a hydrogen atom or a methyl group. X may be any of the foregoing ones, but it more preferably represents —COO—. The symbol m represents 0 or an integer of at least 1, preferably an integer ranging from 2 to 8 and particularly preferably 2. In addition, when m is an integer of at least 2, the functional groups on carbon atoms, which are mutually adjacent to one another, can be linked together to thus form an aliphatic ring. The symbol n represents an integer of at least 1 and preferably an integer ranging from 1 to 10. In this respect, n is particularly preferably an integer ranging from 3 to 6 and the polymeric compound preferably comprises combinations of groups having n values of at least 3, 4, 5 and 6. In particular, the rate of the polymer occupied by the component having an n value of 4 (a constituent of the polymer) is preferably not less than 40% by mole and not more than 97% by mole on the basis of the total amount of the components having n values ranging from 3 to 6 (the components having n values of 3, 4, 5 and 6) or the rate of the polymer occupied by the component having an n of 3 (a constituent of the polymer) is preferably not less than 40% by mole and not more than 97% by mole on the basis of the total amount of the components having n values ranging from 3 to 6 (the components having n values of 3, 4, 5 and 6).

More preferably, the rate of the polymer occupied by the component having an n value of 4 is not less than 60% by mole and not more than 95% by mole and, in particular, not less than 70% by mole and not more than 90% by mole on the basis of the total amount of the components having n values ranging from 3 to 6.

More preferably, the polymeric compounds as the component (B) derived from the fluorinated aliphatic compounds produced according to the telomerization and oligomerization methods are those given below and having the fluorinated aliphatic groups represented by the following general formula (II-1).

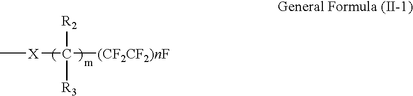

In Formula (II-1), each of R₂ and R₃ independently represents a hydrogen atom or an alkyl group having 1 to 4 carbon atoms; X represents a single bond or a divalent connecting group and is connected to the main chain of the polymer; m represents 0 or an integer of not less than 1; and n is an integer of not less than 1 and not more than 10.

Specific methods for the preparation of the polymeric compound carrying fluorinated aliphatic groups used in the present invention will hereunder be described in more detail. The fluorine atom-containing polymer used in the present invention may be in the form of, for instance, an acrylic resin, a methacrylic resin, a styryl resin, a polyester resin, a polyurethane resin, a polycarbonate resin, a polyamide resin, a polyacetal resin, a phenol/formaldehyde condensation resin, a polyvinyl phenol resin, a maleic anhydride/α-olefinic resin and an α-hetero-substituted methacrylic resin. Among them, preferably used herein are an acrylic resin, a methacrylic resin, a styryl resin, a polyester resin and a polyurethane resin, with an acrylic resin, a methacrylic resin and a polyurethane resin being particularly useful. These resins can easily be prepared from appropriate polymerizable monomers by any method known to those of ordinary skill in the art such as the polycondensation, addition polymerization and ring-opening polymerization techniques. The method will hereunder be described in more specifically while taking acrylic and/or methacrylic resins most useful in the present invention and excellent in the production aptitude, by way of examples.

Examples of acrylic resins preferably used in the invention are those comprising, as copolymer units, the repeating units represented by the following general formula (III).

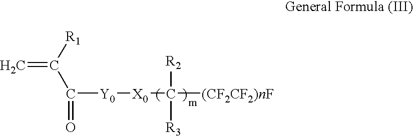

In Formula (III), R₁ represents hydrogen atom, a halogen atom (such as a fluorine, chlorine or bromine atom) or a substituted or unsubstituted methyl group; Y₀ and X₀ each represent a divalent organic group; and R₂ and R₃, m and n are the same as those specified or defined above in connection with the general formula (II). Specific examples of the divalent organic groups represented by Y₀ and X₀ are —O—, —S—, —N(R₄)— and —CO—. The perfluoro-alkyl group-containing monomers used in the invention and represented by Formula (III) have chemical structures such as those listed below:

Specific Examples Thereof Having an n of 4:

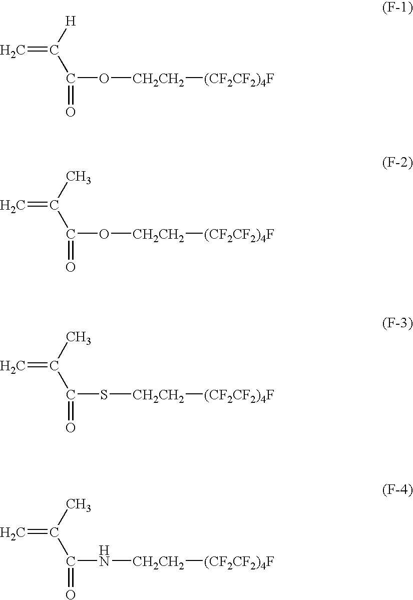

Specific Examples Thereof Having an n of 6:

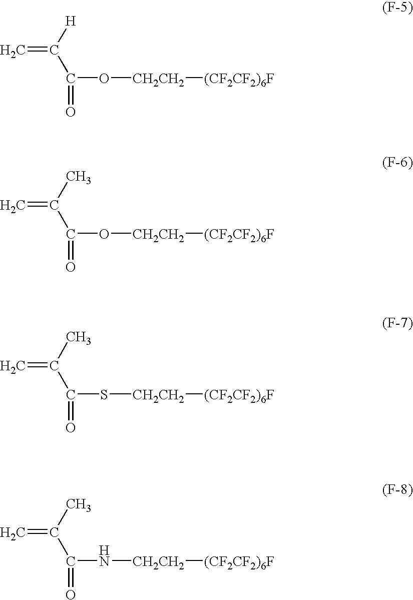

The following are examples of specific structures of the fluorine atom-containing polymers used in the present invention. In the following formulas, each numerical value means the rate (% by mole) of each monomer component.

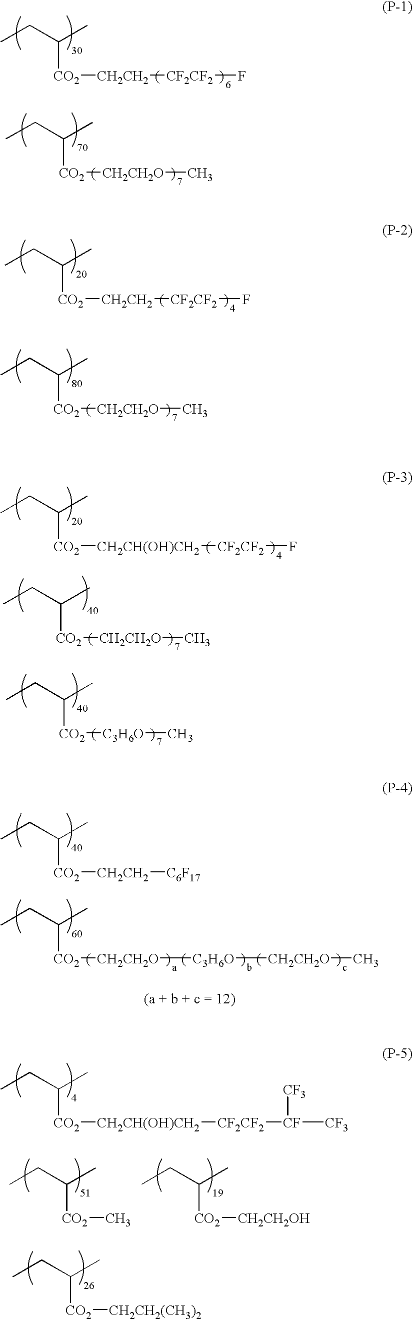

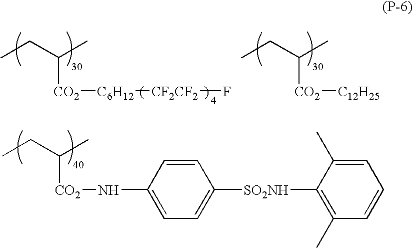

Specific examples of the fluorine atom-containing polymers also include those disclosed in, for instance, J.P. KOKAI 2002-72474, J.P. KOKAI 2002-311577 and J.P. KOKAI 2002-296774. These fluorine atom-containing polymers may be used alone or a mixture comprising at least two of them. The content of fluorine atom-containing polymers in the light-sensitive layer ranges from 0.01 to 20% by weight, preferably 0.2 to 10% by weight and more preferably 0.5 to 5% by weight.

These fluorine atom-containing polymers show an effect of improving the quality of the surface of a light-sensitive layer which is in general formed by dissolving the foregoing components in an organic solvent, followed by the application of the resulting solution and the subsequent drying of the coated layer. As a result of the intensive studies, the inventors of this invention have found that the foregoing fluorine atom-containing polymer may be incorporated into the infrared light-sensitive layer which comprises the polymer of Formula (I) as the component (A) according to the present invention to thus improve the developing latitude of the coated layer in addition to the foregoing effect of improving the surface quality of the layer.

Further the inventors of this invention have likewise found that an organic acid and/or an acid anhydride as the component (D) as will be detailed later may be used in combination with the foregoing components to thus further improve the developing latitude.

The light-heat conversion substance as the component (C) (hereunder also referred to as simply “component (C)”) used in the present invention is not restricted to any specific one insofar as the substance can absorb infrared light rays and generate heat and examples thereof are dyes capable of absorbing infrared light rays (infrared light-absorbing dyes) and a variety of pigments known as those capable of absorbing infrared light rays (infrared light-absorbing pigments) as well as infrared light-absorbing dyes other than the foregoing ones.

Examples of such pigments usable herein are commercially available ones, and those disclosed in, for instance, Color Index (C.I.) Handbook; “Handbook of Up-To-Date Pigments” (edited by Society of Pigment Engineering in Japan, published in 1977); “Applied Techniques for Up-To-Date Pigments” (CMC Publishing Co., Ltd., 1986); and “Techniques for Printing Ink” (CMC Publishing Co., Ltd., 1984).

The pigments usable herein may be a variety of pigments such as black-colored pigments, yellow-colored pigments, orange-colored pigments, brown-colored pigments, red-colored pigments, purple-colored pigments, blue-colored pigments, green-colored pigments, fluorescent pigments, metal powder pigments, and further polymer-linked dyes. More specifically, examples thereof usable herein are insoluble azo dyes, azo lake pigments, condensed azo pigments, chelating azo pigments, phthalocyanine type pigments, anthraquinone type pigments, perylene and perynone type pigments, thio-indigo type pigments, quinacridone type pigments, dioxazine type pigments, iso-indolinone type pigments, quinophthalone type pigments, sensitizing lake pigments, azine type pigments, nitroso pigments, nitro pigments, naturally occurring pigments, fluorescent pigments, inorganic pigments and carbon black.

These pigments may be used without subjecting them to any surface treatment or after an appropriate surface treatment. Such surface-treatments which may be used herein are, for instance, those comprising the step of coating the surface thereof with a resin or a wax; those comprising the step of applying a surfactant to the surface thereof, and those comprising the step of treating the surface of pigments with a reactive substance (such as a silane coupling agent, an epoxy compound and/or a polyisocyanate) to thus form linkages between them. The foregoing surface-treating methods are disclosed in, for instance, “Characteristic Properties and Applications of Metal Soap” (published by SAIWAY SHOBO); “Techniques for Printing Ink” (CMC Publishing Co., Ltd., 1984); and “Applied Techniques for Up-To-Date Pigments” (CMC Publishing Co., Ltd., 1986).

The particle size of the pigment used herein preferably ranges from 0.01 to 10 μm, more preferably 0.05 to 1 μm and particularly preferably 0.1 to 1 μm. If the particle size of the pigment used is less than 0.01 μm, the pigment particles have insufficient stability in the dispersion as the coating liquid for preparing a light-sensitive layer, while if it exceeds 10 μm, the uniformity of the resulting light-sensitive layer is insufficient.

The pigment particles may be dispersed in coating liquid by any known dispersion techniques used in, for instance, the preparation of ink and toner particles. The dispersion devices used herein are, for instance, ultrasonic dispersion devices, sand mills, attritors, pearl mills, super mills, ball mills, impellers, dispersers, KD mills, colloid mills, dynatrons, three-roll mills, and pressure kneaders. The details thereof can be found in “Applied Techniques for Up-To-Date Pigments” (CMC Publishing Co., Ltd., 1986).

As dyes usable herein, there may be listed, for instance, any known ones such as commercially available dyes and those disclosed in articles (such as “Handbook of Dyes” edited by Society of Organic Synthetic Chemistry, Showa 45 (1970)). Specific examples thereof are azo dyes, metal complex azo dyes, pyrazolone dyes, anthraquinone dyes, phthalocyanine dyes, carbonium dyes, quinoneimine dyes, methine dyes and cyanine dyes.

Among the foregoing pigments and dyes, particularly preferably used in the present invention are those capable of absorbing light rays falling within the infrared to near infrared regions since they are suitably used in combination with lasers emitting light rays falling within the infrared to near infrared regions.

As such pigments capable of absorbing infrared and near infrared light rays, carbon black may preferably be used herein.

In addition, examples of dyes capable of absorbing infrared and near infrared light rays include cyanine dyes such as those disclosed in, for instance, J.P. KOKAI Nos. Sho 58-125246, Sho 59-84356 and Sho 60-78787 and U.S. Pat. No. 4,973,572; methine dyes such as those disclosed in, for instance, J.P. KOKAI Nos. Sho 58-173696, Sho 58-181690 and Sho 58-194595; naphthoquinone dyes such as those disclosed in, for instance, J.P. KOKAI Nos. Sho 58-112793, Sho 58-224793, Sho 59-48187, Sho 59-73996, Sho 60-52940 and Sho 60-63744; squarylium dyestuffs such as those disclosed in, for instance, J.P. KOKAI Nos. Sho 58-112792; cyanine dyes such as those disclosed in, for instance, G.B. Patent No. 434,875; and dihydro-pyrimidine squarylium dyes such as those disclosed in, for instance, U.S. Pat. No. 5,380,635.

Moreover, suitably and preferably used herein as the foregoing dyes also include near infrared light-absorbable sensitizing agents disclosed in U.S. Pat. No. 5,156,938; arylbenzo-(thio)-pyrylium salts disclosed in U.S. Pat. No. 3,881,924; trimethine-thiapyrylium salts disclosed in J.P. KOKAI Sho 57-142645 (U.S. Pat. No. 4,327,169); pyrylium type compounds disclosed in, for instance, J.P. KOKAI Nos. Sho 58-181051, Sho 58-220143, Sho 59-41363, Sho 59-84248, Sho 59-84249, Sho 59-146063 and Sho 59-146061; cyanine dyes disclosed in, for instance, J.P. KOKAI Sho 59-216146; penta-methine thiopyrylium salts disclosed in U.S. Pat. No. 4,283,475; pyrylium compounds disclosed in Japanese Examined Patent Publication (hereunder referred to as “J.P. KOKOKU”) Nos. Hei 5-13514 and Hei 5-19702; and Epolight III-178, Epolight III-130, Epolight III-125 and Epolight IV-62A.

In addition, other examples of the foregoing dyes particularly preferably used herein are near infrared light-absorbing dyes such as those represented by the general formulas (I) and (II) disclosed in U.S. Pat. No. 4,756,993.

These dyes or pigments may be incorporated into the foregoing light-sensitive layer in an amount ranging from 0.01 to 50% by weight, preferably 0.1 to 10% by weight and particularly preferably 0.5 to 10% by weight in case of dyes and 3.1 to 10% by weight in case of pigments, on the basis of the total solid content of the light-sensitive layer.

If the added amount of the pigment or dye is not less than 0.01% by weight, the resulting light-sensitive layer has excellent sensitivity, while if it is not more than 50% by weight, the resulting image-recording layer shows sufficient uniformity and durability.

These dyes or pigments may be added to a layer together with the other components or they may likewise be added to another layer separately formed. When they are added to a separate layer, they are desirably added to a layer in the proximity to that containing a heat-decomposable substance which can substantially reduce the solubility of an alkaline-soluble polymer compound when it is not decomposed. Moreover, it is preferred to incorporate, into the same layer, these dyes or pigments and the alkaline-soluble polymer compound, but these components may be added to separate layers.

The infrared light-sensitive layer used in the present invention may comprise (D) an organic acid and/or a cyclic acid anhydride in addition to the foregoing components (A) to (C). The organic acid and/or the cyclic acid anhydride as the component (D) are preferably used in combination with the foregoing other components since they would permit the achievement of further improved developing latitude.

The organic acid as the component (D) means a compound other than the so-called polymer, it preferably has a molecular weight of not more than 500 and more preferably not more than 300 and preferably has a pKa value, as determined at 25° C. in water, of not more than 9 and more preferably not more than 6.

Examples of such organic acids include those selected from the group consisting of sulfonic acids, sulfinic acids, alkylsulfuric acids, phosphonic acids, phosphinic acids, phosphoric acid esters, carboxylic acids, phenols, sulfonamides and sulfonimides.

Specific examples thereof are p-toluenesulfonic acid, dodecyl benzene-sulfonic acid, mesitylene-sulfonic acid, methane-sulfonic acid, ethane-sulfonic acid, benzene-sulfonic acid, m-benzene di-sulfonic acid, p-toluene-sulfinic acid, benzene-sulfinic acid, methane-sulfinic acid, phenyl-phosphonic acid, methyl-phosphonic acid, chloromethyl-phosphonic acid, dimethyl-phosphinic acid, diphenyl phosphate diphenyl phosphite, and ethyl-sulfuric acid. In addition, specific examples of the organic acids further include trifluoroacetic acid, trichloroacetic acid, 2,6-dichlorobenzoic acid, picric acid, benzoic acid, iso-phthalic acid, oxalic acid, maleic acid, adipic acid, p-toluic acid, 3,4-dimethoxy benzoic acid, phthalic acid, terephthalic acid, 1,4-cyclohexene-2,2-dicarboxylic acid, erucic acid, lauric acid, n-undecanoic acid, and ascorbic acid.

Examples of phenols are 4,4′-bishydroxyphenyl sulfone, bisphenol A, p-nitro-phenol, p-ethoxy-phenol, 2,3,4-trihydroxy-benzophenone, 4-hydroxybenzophenone, 2,4,4-trihydroxy-benzophenone, 4,4′,4″-trihydroxy-triphenyl methane and 4,4′,3″,4″-tetrahydroxy-3,5,3′,5′-tetramethyl-triphenyl methane.

Specific examples of sulfonamides include N-(p-aminosulfonyl-phenyl) methacrylamide, p-aminosulfonyl-phenylamide, and aminosulfonyl-benzene.

The sulfonimides may, for instance, be compounds each having an active imide group (—CO—NH—SO₂—) and specific examples thereof include N-(p-toluene-sulfonyl) methacrylamide and N-(p-toluene-sulfonyl) acrylamide.

Specific examples of cyclic acid anhydrides include phthalic acid anhydride, tetrahydro-phthalic acid anhydride, hexahydro-phthalic anhydride, 3,6-endoxy˜Δ4˜tetrahydro-phthalic acid anhydride, tetrachloro-phthalic acid anhydride, maleic acid anhydride, chloro-maleic acid anhydride, α-phenyl-maleic acid anhydride, succinic acid anhydride and pyromellitic acid anhydride, as disclosed in U.S. Pat. No. 4,115,128.

These organic acids and cyclic acid anhydrides may be used alone, but they are preferably used in any combination of at least two of them. The total amount of these organic acid and cyclic acid anhydride to be incorporated into the light-sensitive layer ranges from 0.1 to 40% by weight and preferably 1 to 30% by weight and more preferably 5 to 20% by weight.

Other components will be described below in detail, which can be incorporated into the light-sensitive layer of the present invention.

The light-sensitive layer of the present invention may additionally comprise, for instance, an agent for obtaining a visible image immediately after the imagewise exposure of the layer, a dye as an image-coloring agent and other fillers.

Examples of the agents for obtaining visible images immediately after the imagewise exposure of the layer include combinations of acid-generating agents which can release acids by the action of the heat generated through the exposure with organic dyes which can change their color tone through the formation of salts with the acids thus released from the former.

Examples of such acid-generating agents include o-naphthoquinone-diazide-4-sulfonic acid halogenides such as those disclosed in J.P. KOKAI No. Sho 50-36209; trihalomethyl-2-pyrone or trihalomethyl-s-triazine such as those disclosed in J.P. KOKAI No. Sho 53-36223; a variety of o-naphthoquinone-diazide compounds such as those disclosed in J.P. KOKAI No. Sho 55-62444; 2-trihalomethyl-5-aryl-1,3,4-oxadiazole compounds such as those disclosed in J.P. KOKAI No. Sho 55-77742; and diazonium salts. These compounds may be used alone or in any combination and the amount thereof to be incorporated into the light-sensitive layer preferably ranges from 0.3 to 15% by weight on the basis of the total mass of the light-sensitive layer.

The light-sensitive layer according to the present invention may comprise at least one of the organic dye which can change its color tone through the formation of a salt with the acid released from the foregoing acid-generating agent.

Examples of such organic dyes usable herein are diphenyl-methane type, triaryl-methane type, thiazine type, oxazine type, phenazine type, xanthene type, anthraquinone type, imino-naphthoquinone type and azomethine type ones. Specific examples thereof include those listed below:

Brilliant Green, Eosine, Ethyl Violet, Erythrosine B, Methyl Green, Crystal Violet, Basic Fuchsine, Phenolphthalein, 1,3-diphenyl-triazine, Alizarin Red S, Thymolphthalein, Methyl Violet 2B, Quinaldine Red, Rose Bengale, Thymolsulfo-phthalein, Xylenol Blue, Methyl-Orange, Orange IV, diphenyl thiocarbazone, 2,7-dichloro-fluorescein, p-Methyl Red, Congo Red, Benzopurpurine 4B, α-Naphthyl Red, Nile Blue 2B, Nile Blue A, Phenacetaline, Methyl Violet, Malachite Green, p-Fuchsine, Oil Blue #603 (available from ORIENT Chemical Industries, Ltd.), Oil Pink #312 (available from ORIENT Chemical Industries, Ltd.), Oil Red 5B (available from ORIENT Chemical Industries, Ltd.), Oil Scarlet #308 (available from ORIENT Chemical Industries, Ltd.), Oil Red OG (available from ORIENT Chemical Industries, Ltd.), Oil Red RR (available from ORIENT Chemical Industries, Ltd.), Oil Green #502 (available from ORIENT Chemical Industries, Ltd.), Spilon Red BEH Special (available from Hodogaya Chemical Co., Ltd.), Victoria Pure Blue BOH (available from Hodogaya Chemical Co., Ltd.), Patent Pure Blue (available from Sumitomo-Mikuni Chemical Industries, Ltd.), Sudan Blue II (available from BASF Company), m-Cresol Purple, Cresol Red, Rhodamine B, Rhodamine 6G, Fast Acid Violet R, Sulfo-Rhodamine B, Auramine, 4-p-diethylaminophenyl-imino-naphthoquinone, 2-carboxyanilino-4-p-di-ethylaminophenyl-imino-naphthoquinone, 2-carbostearylamino-4-p-dihydrooxyethyl-aminophenyl-imino-naphthoquinone, p-methoxybenzoyl-p′-diethylamino-o′-methyl-phenyl-imino-acetanilide, cyano-p-diethylamino-phenyl-imino-acetanilide, 1-phenyl-3-methyl-4-p-diethylamino-phenyl-imino-5-pyrazolone, and 1˜β˜naphthyl-4-p-diethyl-aminophenyl-imino-5-pyrazolone.

Particularly preferred organic dyes are triaryl-methane type ones. Among these triaryl-methane type organic dyes, particularly useful are those having counter anions derived from sulfonic acid compounds such as those disclosed in J.P. KOKAI Sho 62-2932471 and Japanese Patent No. 2,969,021.

These dyes may be used alone or in any combination and the amount thereof to be incorporated into the light-sensitive layer preferably ranges from 0.3 to 15% by weight on the basis of the total mass of the layer. Moreover, these dyes may be used, if necessary, in combination with other dyes and/or pigments and the amount thereof is preferably not more than 70% by weight and more preferably not more than 50% by weight on the basis of the total mass of the dyes and/or pigments.

In addition, the light-sensitive layer of the present invention may further include a variety of additives, depending on various purposes, for instance, a variety of resins each having hydrophobic groups for the improvement of the ink-receptivity of images such as octyl-phenol/formaldehyde resins, t-butyl-phenol/formaldehyde resins, t-butyl-phenol/benzaldehyde resins, rosin-modified novolak resins, and o-naphthoquinone diazide sulfonic acid esters of these modified novolak resins; plasticizers for improving the flexibility of coated films such as dibutyl phthalate, dioctyl phthalate, butyl glycolate, tricresyl phosphate, and dioctyl adipate. The amount of these additives to be incorporated into the light-sensitive layer preferably ranges from 0.01 to 30% by weight on the basis of the total mass of the layer.

Furthermore, the light-sensitive layer of the present invention may comprise a known resin for the further improvement of the wear resistance of the resulting film. Examples of such resins are polyurethane resins, epoxy resins, vinyl chloride resins, nylons, polyester resins, and acrylic resins, which may be used alone or in any combination. The amount thereof to be added preferably ranges from 2 to 40% by weight on the basis of the light-sensitive layer.

In addition, the light-sensitive layer of the present invention may likewise comprise a nonionic surfactant such as those disclosed in, for instance, J.P. KOKAI Nos. Sho 62-251740 and Hei 4-68355; and/or a twitter ionic or amphoteric surfactant such as those disclosed in, for instance, J.P. KOKAI Nos. Sho 59-121044 and Hei 4-13149. In this respect, specific examples of such nonionic surfactants are sorbitan tri-stearate, sorbitan mono-palmitate, sorbitan tri-oleate, stearic acid mono-glyceride, polyoxyethylene sorbitan mono-oleate, and polyoxyethylene nonyl phenyl ether. On the other hand, specific examples of amphoteric surfactants are alkyl di(aminoethyl) glycine, alkyl polyaminoethyl glycine hydrochloride, AMORGEN K (the trade name of N-tetradecyl-N,N-betaine type amphoteric surfactants available from Dai-ichi Kogyo Seiyaku Co., Ltd), 2-alkyl-N-carboxyethyl-N-hydroxyethyl imidazolinium betaine and LEBON 15 (the trade name of alkyl imidazoline type amphoteric surfactants available from Sanyo Chemical Industries, Ltd.).

The rate of the light-sensitive layer occupied by the foregoing nonionic surfactant and amphoteric surfactant preferably ranges from 0.05 to 15% by weight and more preferably 0.1 to 5% by weight.

Improvement of Surface Quality of Coated Layer: The light-sensitive layer of the present invention may comprise, in addition to the fluorine atom-containing polymer as the component (B), a surfactant for the improvement of the surface quality of the coated layer such as a fluorine atom-containing surfactant as disclosed in, for instance, J.P. KOKAI Sho 62-170950. The amount thereof to be incorporated into the light-sensitive layer preferably ranges from 0.001 to 1.0% by weight and more preferably 0.005 to 0.5% by weight on the basis of the total mass of the light-sensitive layer.

Moreover, the light-sensitive layer of the present invention may comprise a yellow-colored dye and preferably one whose absorbance at 417 nm is not less than 70% of the absorbance observed at 436 nm.

The light-sensitive layer of the present invention may be formed by dissolving or dispersing the foregoing components for forming the light-sensitive layer of the invention in an organic solvent or a mixture thereof, followed by the application of the resulting solution or dispersion onto a substrate and subsequent drying of the resulting coated layer.

The organic solvent usable herein may be any known and commonly used one, but I is preferred to select an organic solvent having a boiling point ranging from 40 to 200° C., in particular, 60 to 160° C. because of the advantage in the drying step.

Specific examples of such organic solvents are alcohols such as methyl alcohol, ethyl alcohol, n- or iso-propyl alcohol, n- or iso-butyl alcohol and diacetone alcohol; ketones such as acetone, methyl ethyl ketone, methyl propyl ketone, methyl butyl ketone, methyl amyl ketone, methyl hexyl ketone, diethyl ketone, di-isobutyl ketone, cyclohexanone, methyl cyclohexanone and acetyl acetone; hydrocarbons such as benzene, toluene, xylene, cyclohexane and methoxy benzene; acetic acid esters such as ethyl acetate, n- or iso-propyl acetate, n- or iso-butyl acetate, ethyl butyl acetate and hexyl acetate; halogenated compounds such as methylene dichloride, ethylene dichloride and monochloro-benzene; ethers such as isopropyl ether, n-butyl ether, dioxane, dimethyl dioxane and tetrahydrofuran; polyhydric alcohols and derivatives thereof such as ethylene glycol, methyl cellosolve, methyl cellosolve acetate, ethyl cellosolve, diethyl cellosolve, cellosolve acetate, butyl cellosolve, butyl cellosolve acetate, methoxy-methoxy ethanol, diethylene glycol monomethyl ether, diethylene glycol dimethyl ether, diethylene glycol methyl ethyl ether, diethylene glycol diethyl ether, propylene glycol, propylene glycol monomethyl ether, propylene glycol monomethyl ether acetate, propylene glycol monoethyl ether, propylene glycol monoethyl ether acetate, propylene glycol mono-butyl ether and 3-methyl-3-methoxy butanoyl; dimethylsulfoxide; and N,N-dimethylformamide. The concentration of the solid contents present in the coating solution suitably ranges from 2 to 50% by weight.

The light-sensitive layer of the present invention is applied onto a substrate according to various methods such as roll coating, dip coating, air-knife coating, gravure coating, gravure offset coating, hopper coating, blade coating, wire doctor coating and spray coating techniques. In this respect, the coated amount of the light-sensitive layer preferably ranges from 0.3 to 4.0 g/m² as expressed in terms of the weight thereof after drying. The smaller the coated amount of the layer, the smaller the exposure value required for forming images thereon, but the strength of the resulting film is reduced. On the other hand, the higher the coated amount of the layer, the higher the exposure value required for forming images thereon, but the resulting film has a higher film-strength. For instance, if the light-sensitive layer is used as a material for preparing a lithographic printing plate, the resulting plate would ensure a high printing durability (or it can provide a large number of printed matters).

The light-sensitive layer applied to or coated on a substrate is in general dried using air heated. The temperature of the air used for the drying preferably ranges from 30 to 200° C. and, in particular, 40 to 140° C. In the drying method, the drying temperature may be maintained at a constant level or may gradually or stepwise be raised. Alternatively, good results may sometime be obtained by the removal of the moisture present in the air for drying. The heated air used for drying is preferably fed to the coated surface in a flow rate ranging from 0.1 to 30 m/sec and, in particular, 0.5 to 20 m/sec.

[Substrate]

The substrate used in the present invention is a dimensionally stable plate-like material and examples thereof include paper; paper laminated with a plastic film (such as polyethylene, polypropylene or polystyrene film); metal plates (such as aluminum, zinc and copper plates); plastic films (such as films of, for instance, cellulose diacetate, cellulose triacetate, cellulose propionate, cellulose butyrate, cellulose butyrate acetate, cellulose nitrate, polyethylene terephthalate, polyethylene, polystyrene, polycarbonate and polyvinyl acetal); and paper or plastic films on which the foregoing metals are deposited, or paper or plastic films laminated with foils of the foregoing metals, with polyester films or aluminum plates being preferably used in the present invention as the materials for the substrate. Among them, particularly preferred are aluminum plates because of their dimensional stability and relatively low price. Examples of aluminum plates suitably used herein are a pure aluminum plate and an aluminum alloy plate which mainly comprises aluminum and trace amounts of foreign elements. The substrate may likewise be a plastic film having an aluminum layer deposited thereon or laminated with an aluminum foil. The foreign elements included in the aluminum alloy may be, for instance, silicon, iron, manganese, copper, magnesium, chromium, zinc, bismuth, nickel and titanium. The content of these foreign elements present in the aluminum alloy is on the order of at most 10% by weight based on the total mass of the alloy. Particularly preferred aluminum plates used in the present invention are pure aluminum plates, but it is difficult to produce completely pure aluminum from the viewpoint of the limit in the refining technique. Accordingly, the aluminum plate used herein may be one containing a trace amount of foreign elements. The composition of such an aluminum plate used in the present invention is not restricted to any particular one and any aluminum plate produced from any conventionally known or currently used material may appropriately be used without any particular restriction. The thickness of the aluminum plate used in the invention ranges from about 0.1 to 0.6 mm, preferably 0.15 to 0.4 mm and particularly preferably 0.2 to 0.3 mm.

The aluminum plate is subjected to a surface-roughening treatment, but the surface of the aluminum plate may, if necessary, be subjected to a degreasing treatment using, for instance, a surfactant, an organic solvent or an alkaline aqueous solution for the removal of the rolling oil present on the surface prior to the surface-roughening treatment of the aluminum plate. The aluminum plate may be surface-roughened according to a variety of methods, for instance, a method for mechanically roughening the surface, a method in which the surface of the plate is electrochemically dissolved to thus roughen the surface thereof and a method in which the surface of the plate is selectively dissolved chemically to thus roughen the same. Examples of mechanical surface-roughening methods are any known one such as ball-polishing methods, brush-polishing methods, blast-polishing methods and buff-polishing methods. In addition, the electrochemical surface-roughening treatment may, for instance, be one in which the plate is electrochemically treated in an electrolyte such as a solution of hydrochloric acid or nitric acid using a direct or alternating current. It is also possible to use the combination of these two methods as disclosed in J.P. KOKAI Sho 54-63902. The aluminum plat thus surface-roughened is, if necessary, subjected to an alkali-etching treatment and a neutralization treatment and then, if desired, subjected to an anodization treatment for the improvement of the water retention characteristics and wear resistance of the surface. A variety of electrolytes may be used in the anodization treatment of an aluminum plate, insofar as they can form a porous anodized film or layer and examples thereof commonly used include solutions of sulfuric acid, phosphoric acid, oxalic acid, chromic acid or mixture thereof. The concentration of the electrolyte is appropriately determined depending on the kinds thereof.

The conditions for the anodization treatment may vary depending on the electrolyte selected and cannot unconditionally be determined, but it is usually sufficient to anodize the aluminum plate under the following conditions: an electrolyte concentration ranging from 1 to 80% by weight; an electrolyte temperature ranging from 5 to 70° C.; a current density ranging from 5 to 60 A/dm²; a voltage ranging from 1 to 100 V; and an electrolyzation time ranging from 10 seconds to 5 minutes. In this connection, if the quantity of the anodized film to be formed is less than 1.0 g/m², the resulting printing plate has insufficient printing durability, the non-image area of the lithographic printing plate may easily be damaged and this in turn results in the adhesion of ink to the damaged portion or the printing plate is quite susceptible to the so-called “contamination due to defects” during printing operations. After the anodization treatment, the surface of the aluminum plate is, if necessary, subjected to a hydrophilization treatment. The hydrophilization treatment used herein may be, for instance, a method in which the surface of an aluminum plate is treated with an alkali metal silicate (such as an aqueous solution of sodium silicate) as disclosed in U.S. Pat. Nos. 2,714,066, 3,181,461, 3,280,743 and 3,902,734. In this method, the substrate is treated by dipping it in an aqueous solution of sodium silicate or it is electrolyzed. The hydrophilization treatment used herein may further include methods in which the substrate is treated with potassium fluorozirconate (see, for instance, J.P. KOKOKU Sho 36-22063) and polyvinyl phosphonic acid (see, for instance, U.S. Pat. Nos. 3,276,868, 4,153,461 and 4,689,272.

[Organic Undercoating Layer]

In the present invention, an organic undercoating layer (hereunder simply referred to as “undercoating layer”) is preferably applied onto the substrate which has been hydrophilized prior to the application of a light-sensitive layer in order to reduce the amount of the remaining light-sensitive layer on the non-image areas. Examples of organic compounds used in such an undercoating layer include carboxymethyl cellulose, dextrin, gum Arabic, phosphonic acids carrying amino groups such as 2-aminoethyl phosphonic acid, substituted or unsubstituted organic phosphonic acids such as phenyl phosphonic acids, naphthyl phosphonic acids, alkyl phosphonic acids, glycero-phosphonic acids, methylene diphosphonic acids and ethylene diphosphonic acids, substituted or unsubstituted organic phosphoric acids such as phenyl phosphoric acid, naphthyl phosphoric acid, alkyl phosphoric acid and glycero-phosphoric acid, substituted or unsubstituted organic phosphinic acids such as phenyl phosphinic acid, naphthyl phosphonic acid, alkyl phosphonic acid and glycero-phosphonic acid, amino acids such as glycine and β-alanine, and hydroxyl group-containing amine hydrochlorides such as triethanolamine hydrochloride. These organic compounds may be used alone or in any combination.

It is also preferred to use an onium group-containing compound in th organic undercoating layer. The onium group-containing compound is detailed in, for instance, J.P. KOKAI Nos. 2000-10292 and 2000-108538.

Moreover, it is also possible to use at least one compound selected from the group consisting of polymers each having, in the molecule, structural units represented by, for instance, poly(p-vinyl benzoic acid). Specific examples of such polymers include copolymers of p-vinyl benzoic acid with vinyl-benzyl triethyl ammonium salt, and copolymers of p-vinyl benzoic acid with vinyl-benzyl trimethyl ammonium chloride.

This organic undercoating layer may be applied onto the surface of a substrate according to the following method. More specifically, the layer may be formed by a method which comprises the steps of dissolving the foregoing organic compounds in water, an organic solvent such as methanol, ethanol and methyl ethyl ketone or a mixture thereof, applying the resulting solution onto the surface of an aluminum plate and then drying the coated layer; or a method comprising the steps of dissolving the foregoing organic compounds in water, an organic solvent such as methanol, ethanol and methyl ethyl ketone or a mixture thereof, dipping an aluminum plate in the resulting solution to thus adhere the foregoing organic compound on the plate surface, washing with, for instance, water and then drying the plate to thus form an organic undercoating layer. In the former method, a solution of the foregoing organic compound having a concentration ranging from 0.005 to 10% by weight can be applied onto the surface of the aluminum plate according to a variety of coating techniques. Examples of such coating techniques usable herein are bar coater coating, whirler coating, spray coating and curtain coating techniques. In addition, in the latter coating method, the concentration of the solution ranges from 0.01 to 20% by weight and preferably 0.05 to 5% by weight; the dipping temperature ranges from 20 to 90° C. and preferably 25 to 50° C.; and the dipping time ranges from 0.1 second to 20 minutes and preferably 2 seconds to one minute.

The pH value of the solution used in this method may be controlled to the range of from 1 to 12 using a basic substance such as ammonia, triethylamine or potassium hydroxide or an acidic substance such as phosphoric acid, prior to the practical use of the same. It is also possible to add a yellow dye to the treating solution in order to improve the tone reproduction of the resulting light-sensitive lithographic printing plate. Moreover, a compound represented by the following general formula (a) may be incorporated into the dipping solution:
(HO)ₓ—R₅—(COOH)_{y} General Formula (a)

Wherein R₅ represents a substituted or unsubstituted arylene group having not more than 14 carbon atoms and x and y independently represent an integer ranging from 1 to 3. Specific examples of the compound represented by Formula (a) are 3-hydroxybenzoic acid, 4-hydroxybenzoic acid, salicylic acid, 1-hydroxy-2-naphthoic acid, 2-hydroxy-1-naphthoic acid, 2-hydroxy-3-naphthoic acid, 2,4-dihydroxybenzoic acid and 10-hydroxy-9-anthracene carboxylic acid. The coated amount of the undercoating layer as determined after drying suitably ranges from 1 to 100 mg/m² and preferably 2 to 70 mg/m². In this respect, if the coated amount is less than the lower limit: 1 mg/m², any lithographic printing plate cannot be obtained, which has satisfactory printing durability. The same is true in case where the coated amount is greater than the upper limit: 100 mg/m².

[Imagewise Exposure and Developing Treatment]

The light sources used for the exposure of the light-sensitive lithographic printing plate according to the present invention are preferably solid lasers and semiconductor lasers capable of emitting infrared light rays having wavelengths which fall within the range of from 760 to 1200 nm.

In the present invention, the light-sensitive layer may be subjected to a developing treatment immediately after the irradiation of the layer with a laser beam, but it is preferred that the layer is heat-treated after the laser beam-exposure step and the developing step. The heat treatment is preferably carried out at a temperature ranging from 80 to 150° C. for 10 seconds to 5 minutes. This heat treatment would permit the reduction of the laser energy required for the recording of images by the irradiation with a laser beam. Accordingly, the light-sensitive lithographic printing plate of the present invention is, if necessary, heat-treated and then developed.

The developer which can be applied to the development of the light-sensitive lithographic printing plate is one having a pH value ranging from 9.0 to 14.0 and preferably 12.0 to 13.5. The developer usable herein (hereunder the term “developer” used herein also includes the replenisher for the developer) may be any conventionally known alkaline aqueous solution. Examples of alkalis usable in the invention are inorganic alkali salts such as sodium silicate, potassium silicate, sodium tertiary phosphate, potassium tertiary phosphate, ammonium tertiary phosphate, sodium secondary phosphate, potassium secondary phosphate, ammonium secondary phosphate, sodium carbonate, potassium carbonate, ammonium carbonate, sodium hydroxide, potassium hydroxide, ammonium hydroxide and lithium hydroxide. Examples of alkalis usable in the invention also include organic alkaline agents such as mono-methylamine, di-methylamine, tri-methylamine, mono-ethylamine, di-ethylamine, tri-ethylamine, mono-isopropylamine, di-isopropylamine, tri-isopropylamine, n-butyl-amine, mono-ethanolamine, di-ethanolamine, tri-ethanolamine, mono-isopropanol-amine, di-isopropanolamine, ethyleneimine, ethylenediamine, and pyridine. These alkaline agents may be used in the foregoing alkaline aqueous solution as the developer alone or in any combination of at least two of them.

One of the developers, which can ensure the intended effect of the present invention, among the foregoing alkaline aqueous solutions, is an aqueous solution or the so-called “silicate developer” which comprises an alkali silicate as a base or an alkali silicate obtained by admixing a base with a silicon compound and having a pH value of not less than 12; or another developer more preferably used herein is the so-called “non-silicate developer” which is free of any alkali silicate and comprises a non-reducing saccharide or salicylic acid (an organic compound having a buffering action) and a base.

The developing ability of the former developer may be controlled by appropriately adjusting the concentrations of the silicon oxide SiO₂ and the alkali metal oxide M₂O as the components of the silicate present in the aqueous solution of the alkali metal silicate as well as the ratio thereof (in general, this ratio is expressed in terms of the molar ratio thereof: [SiO₂]/[M₂O]). Accordingly, the developers suitably used herein include, for instance, an aqueous solution of sodium silicate whose molar ratio: SiO₂/Na₂O ranges from 1.0 to 1.5 (or the ratio [SiO₂]/[Na₂O] ranges from 1.0 to 1.5), and whose SiO₂ content ranges from 1 to 4% by weight such as those disclosed in J.P. KOKAI Sho 54-62004; and an aqueous solution of alkali metal silicate whose molar ratio: [SiO₂]/[M] ranges from 0.5 to 0.75 (or the molar ratio: [SiO₂]/[M₂O] ranges from 1.0 to 1.5), whose SiO₂ concentration ranges from 1 to 4% by weight and whose potassium content is at least 20% on the basis of the amount (as expressed in terms of the gram atom) of the total alkali metals present in the developer.

In addition, examples of the so-called “non-silicate developers” preferably used herein, which are free of any alkali silicate and comprise a non-reducing saccharide and a base, are those disclosed in J.P. KOKAI Hei 8-305039. This developer is characterized in that it comprises (i) at least one saccharide selected from non-reducing saccharides (such as D-sorbit) and (ii) at least one base and that it has a pH value ranging from 9.0 to 13.5 and when this developer is used for the development of a light-sensitive lithographic printing plate, it never deteriorates the surface of the light-sensitive layer and it can maintain good ink-receptivity of the light-sensitive layer.

The developer usable in the present invention may be one as disclosed in J.P. KOKAI Hei 6-282079. This developer comprises an alkali metal silicate whose molar ratio: SiO₂/M₂O (wherein M represents an alkali metal) ranges from 0.5 to 2.0; and a water-soluble ethylene oxide-added compound obtained by adding not less than 5 moles of ethylene oxide to a sugar alcohol carrying not less than 4 hydroxyl groups.

The light-sensitive lithographic printing plate which has been developed with the foregoing developer is then post-treated with washing water; a rinsing solution containing, for instance, a surfactant; a finisher mainly comprising, for instance, gum Arabic and a starch derivative; and/or a protective gumming solution. These treatments may variously be combined and used in the post-treatment of the light-sensitive lithographic printing plate according to the present invention.

There have widely been used an automatic developing machine in the fields of plate-making and printing industries, in order to ensure the stable operations for the development of imagewise exposed light-sensitive lithographic printing plates. This automatic developing machine in general consists of a developing zone and a post-treating zone and comprises a device for conveying printing plates, tanks each containing a desired processing liquid and a spraying device. In this automatic developing machine, each processing liquid pumped up is sprayed on the printing plates through a spray nozzle while horizontally conveying the imagewise exposed printing plates to thus develop the plates. Recently, there has also been known a method in which an imagewise exposed light-sensitive lithographic printing plate is dipped in a processing liquid contained in the processing tank while conveying the printing plate within the processing liquid by means of submerged guide rolls distributed in the tank to thus develop the plate. In such an automatic developing machine, the printing plates can be processed while supplementing a replenisher to each processing liquid in an amount proportional to the throughput of the printing plates and the operating time of the machine.

The light-sensitive lithographic printing plate of the present invention may be processed using the foregoing automatic developing machine or according to the so-called disposable system in which each fresh processing liquid is fed to the corresponding processing tank for every light-sensitive lithographic printing plate.

If there are some unnecessary image areas on the lithographic printing plate obtained by imagewise exposing a light-sensitive lithographic printing plate of the present invention, developing the imagewise exposed printing plate, water-washing and/or rinsing and/or gumming the plate, the unnecessary image areas are erased. These unnecessary image areas can be erased by any known method.

The lithographic printing plate thus prepared from the light-sensitive lithographic printing plate of the present invention is if desired treated with desensitizing gum and then fed to the printing step, but if it is intended to further improve the printing durability of the resulting printing plate, the gummed printing plate may be subjected to a burning treatment. The burning treatment may be carried out according to any known method. When the lithographic printing plate is subjected to a burning treatment, the plate is preferably treated with a surface-conditioning liquid such as those disclosed in J.P. KOKOKU Nos. Sho 61-2518 and Sho 55-28062 and J.P. KOKAI Nos. Sho 62-31859 and Sho 61-159655.

The lithographic printing plate obtained after such treatments is fitted to, for instance, an offset printing press to thus prepare a large number of printed matters.

### EXAMPLES

The present invention will hereunder be described in more detail with reference to the following Examples, but the present invention is not restricted to these specific Examples at all.

Synthesis of Acetal Polymer of Formula (I) Used in the Invention]

The compound was prepared according to the method disclosed in Tokuhyo 2003-53058.

### Preparation Example 1

### Synthesis of Acetal Polymer A

Mowiol (registered trade mark) 3-98 polyvinyl alcohol (98% hydrolyzed polyvinyl acetate having an average molecular weight of 16000; 110 g) was added to a closed reaction container equipped with a water-cooled condenser, a dropping funnel and a thermometer to which 250 g of desalted water had been introduced. The mixture was heated at 90° C. for one hour with continuous stirring to thus give a transparent solution. Then the temperature of the solution was adjusted to 60° C. and 3 g of concentrated sulfuric acid was added to the solution. To the solution, there was dropwise added a solution of 4-hydroxybenzaldehyde (59.8 g) and 2,6-di-t-butyl-4-methylphenol (1.4 g) in 450 g of 2-methoxyethanol over 15 minutes. The reaction mixture was diluted with 500 g of additional 2-methoxyethanol and a solution of n-butyl aldehyde (35.3 g) in 500 g of 2-methoxyethanol was dropwise added to the solution. After the complete addition of the aldehyde, the reaction was further continued at 50° C. for additional 3 hours. The water was distilled off from the reaction mixture to thus substitute 2-methoxyethanol for the water (the moisture content of the solution or the amount of water remaining in the solution was less than 0.3%). The reaction mixture was neutralized to a pH of 7±0.5 with sodium hydrogen carbonate and then the mixture was blended with 15L of water-methanol mixture (10:1). The polymer precipitated was washed with water, filtered off and dried at 50° C. in a vacuum.

Thus, 165 g (yield: 88.2% as calculated on the basis of PVA) of the title polymer was obtained and the degree of conversion of 4-hydroxybenzaldehyde was found to be 85%. The structure of the resulting polymer corresponded to the foregoing structural formula wherein the group R¹ was derived from n-butyl aldehyde, the group R² was derived from 4-hydroxybenzaldehyde, and the values of m, n, p and q were 36 mole %, 37 mole %, 2 mole % and 25 mole %, respectively (Tg: 63° C.).

### Preparation Example 2

### Synthesis of Acetal Polymer B

Airvol (registered trade mark) 502 polyvinyl alcohol (88% hydrolyzed polyvinyl acetate having an average molecular weight of 16000; 110 g) was added to a closed reaction container equipped with a water-cooled condenser, a dropping funnel and a thermometer to which 110 g of desalted water and 110 g of methanol had been introduced. The mixture was heated at 90° C. for one hour with continuous stirring to thus give a transparent solution. Then the temperature of the solution was adjusted to 60° C. and 3 g of concentrated sulfuric acid in 100 g of PM (1-methoxy-2-propanol; Dowanol (registered trade mark)PM) was added to the solution. To the resulting solution, there was dropwise added a solution of 3-hydroxybenzaldehyde (61 g) and 2,6-di-t-butyl-4-methylphenol (1.4 g) in 450 g of PM over 15 minutes. The reaction mixture was diluted with 200 g of additional PM and a solution of n-butyl aldehyde (18.2 g) and propargyl aldehyde (8.1 g) in 500 g of PM was dropwise added to the solution. After the complete addition of the aldehyde, the reaction was further continued at 50° C. for additional 3 hours. The water was distilled off from the reaction mixture to thus substitute PM for the water. At this stage, the moisture content of the reaction mixture was found to be less than 0.2%. The degree of conversion of m-hydroxy-benzaldehyde into benzal (benzylidene) was found to be quantitative. The reaction mixture was neutralized to a pH of 7±0.5 with sodium hydrogen carbonate and then the mixture was blended with 15 L of water-methanol mixture (10:1). The polymer precipitated was washed with water, filtered off and dried at 50° C. in a vacuum.

Thus, 170 g (yield: 93.7% as calculated on the basis of PVA) of the title polymer was obtained and the degree of conversion of m-hydroxy-benzaldehyde was found to be 100%. The structure of the resulting polymer corresponded to the foregoing structural formula wherein the group R¹ was derived from n-butyl aldehyde, the group R² was derived from 3-hydroxybenzaldehyde, the group R³ was derived from propargyl aldehyde, and the values of m, n, p, o and q were 21 mole %, 43 mole %, 2 mole %, 10 mole % and 24 mole %, respectively (Tg: 65° C.).

### Preparation Example 3

### Synthesis of Acetal Polymer C

Airvol (registered trade mark) 203 polyvinyl alcohol (88% hydrolyzed polyvinyl acetate having an average molecular weight of 18000; 110 g) was added to a closed reaction container equipped with a water-cooled condenser, a dropping funnel and a thermometer to which 110 g of desalted water and 110 g of methanol had been introduced. The mixture was heated at 80° C. for one hour with continuous stirring to thus give a transparent solution. Then the temperature of the solution was adjusted to 60° C. and 3 g of concentrated sulfuric acid in 100 g of PM was added to the solution. To the resulting solution, there was dropwise added a solution of 4-hydroxybenzaldehyde (32 g), 2-hydroxy-1-naphthaldehyde (30 g) and 2,6-di-t-butyl-4-methylphenol (1.4 g) in 500 g of PM over 15 minutes. The reaction mixture was diluted with 200 g of additional PM and a solution of n-butyl aldehyde (21.4 g) in 500 g of PM was dropwise added to the solution. After the complete addition of the aldehyde, the reaction was further continued at 50° C. for additional 3 hours. The water was distilled off from the reaction mixture to thus substitute PM for the water. At this stage, the moisture content of the reaction mixture was found to be less than 0.21%. The degree of conversion of aromatic aldehyde into benzal was found to be quantitative. The reaction mixture was neutralized to a pH of 7±0.5 with sodium hydrogen carbonate and then the mixture was blended with 15 L of water-methanol mixture (10:1). The polymer precipitated was washed with water, filtered off and dried at 50° C. in a vacuum.

Thus, 165 g (yield: 93% as calculated on the basis of PVA) of the title polymer was obtained and the degrees of conversion of 4-hydroxy-benzaldehyde and 2-hydroxy-1-naphthaldehyde were found to be 97%. The structure of the resulting polymer corresponded to the foregoing structural formula wherein the group R¹ was derived from n-butyl aldehyde, the group R² was derived from the mixture of 4-hydroxybenzaldehyde and 2-hydroxy-1-naphthaldehyde, and the values of m, n, p and q were 25 mole %, 38 mole %, 12 mole % and 26 mole %, respectively (Tg: 74° C.).

### Preparation Example of Substrate

An aluminum plate (material: JIS A 1050) having a thickness of 0.3 mm was etched under the following conditions: a caustic soda concentration of 30 g/L; an aluminum concentration of 10 g/L; an etching temperature of 60° C.; and an etching time of 10 seconds, followed by washing of the plate with running water, neutralization and washing thereof with a 10 g/L nitric acid solution and the subsequent washing thereof with water. The plate was then subjected to an electrochemical surface-roughening treatment in an aqueous solution having a hydrogen chloride concentration of 15 g/L, an aluminum ion concentration of 10 g/L at an electrolyte temperature of 30° C., using a sinusoidal alternating waved current under the condition of an applied voltage Va of 20 V and at a quantity of electricity of 40° C./dm², and then the plate was washed with water. Then the aluminum plate was etched with an etching solution having a caustic soda concentration of 30 g/L and an aluminum ion concentration of 10 g/L at a temperature of 40° C. for 10 seconds and washed with running water. Subsequently, the plate was desmutted in a 15% by weight sulfuric acid aqueous solution having a temperature of 30° C. and then washed with water. In addition, the aluminum plate was anodized in a 10% by weight sulfuric acid aqueous solution having a temperature of 20° C. using a direct current at a current density of 6 A/dm² such that the amount of the anodized layer was equal to 2.5 g/m², followed by washing thereof with water and drying the same. Thereafter, the anodized plate was treated with a 1.0% by weight sodium silicate aqueous solution at 30° C. for 10 seconds to thus obtain a hydrophilized substrate (a).

At this stage, the aluminum substrate was inspected for the central line average surface roughness (Ra) using a needle having a diameter of 2 μm and it was found to be 0.43 μm.

[Formation of Undercoating Layer]

The following solution for forming an undercoating layer was applied onto the surface of the substrate (a) thus treated and then the coated layer was dried at 80° C. for 30 seconds to thus form an undercoating layer. The amount of the undercoating layer weighed after drying was found to be 17 mg/m².

(Composition of Undercoating Solution)

| Component | Amt. |
|---|---|
| The following Compound | 0.3 g |
| Methanol | 100 g |
| Water | 1 g |

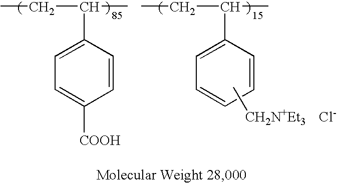

### Examples 1 to 12 and Comparative Examples 1 to 6

The following solution for forming a light-sensitive layer (light-sensitive layer solution) was applied onto the substrate provided with the foregoing undercoating layer, the resulting light-sensitive layer was dried in an oven maintained at 150° C. for one minute to thus give a positive-working light-sensitive lithographic printing plate having a light-sensitive layer of 1.8 g/m² (dry weight).

(Light-Sensitive Layer Solution)

| Component | Amt. (g) |
|---|---|
| Acetal polymer as the component (A) of the invention | 1.2 |
| (see Table 1) | |
| Fluorine atom-containing polymer as the component (B) of the | 0.02 |
| invention (see Table 1) | |
| Organic acid as the component (D) of the invention | 0.06 |
| (see Table 1) | |
| Cyclic acid anhydride as the component (D) of the invention | 0.06 |
| (see Table 1) | |
| Light-heat conversion substance (the following cyanine | 0.04 |
| dye A) as the component (C) of the invention | |
| Dye comprising Victoria Pure Blue BOH whose counter ions | 0.015 |
| were changed to 1-naphthalene sulfonate anions | |
| Methyl ethyl ketone | 15 |
| 1-Methoxy-2-propanol | 7 |

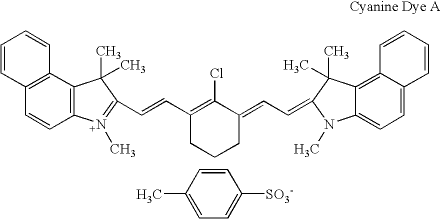

The resulting light-sensitive lithographic printing plate was inspected for the developing latitude and the printing durability, which were evaluated according to the following methods. The results thus obtained are summarized in the following Table 1.

[Evaluation of Developing Latitude]

A test pattern was written, like images, on the resulting light-sensitive lithographic printing plate using Trendsetter available from Creo Company at a beam strength of 9W and a drum-rotational speed of 150 rpm.

Then the imagewise exposed plate was developed for 20 seconds using PS Processor 900H available from Fuji Photo Film Co., Ltd. which had been charged with an alkaline developer A maintained at a temperature of 30° C. and having the following composition. Then a 3% by weight potassium hydroxide aqueous solution was added to the developer according to need to thus stepwise increase the electrical conductance of the developer by a constant value, while the light-sensitive lithographic printing plate was developed with the developer having each specific electrical conductance; and thereafter the electrical conductance of the developer was reduced, by a constant value, by passing carbon dioxide gas through the alkaline developer A to thus form a several kinds of developers having different low electrical conductance values (or low activities), while the light-sensitive lithographic printing plate was developed with the developer having each specific electrical conductance to thus determine the maximum and minimum electrical conductance values of the developer, at which the image area was never dissolved out, which did not cause any contamination and/or coloration due to any insufficient development of the non-image area or any remaining film and which permitted excellent development and the difference between them was determined and this was defined to be “developing latitude”.

<Composition of Alkaline Developer A>

| Component | Amt. (part by weight) |
|---|---|
| SiO₂.K₂O (K₂O/SiO₂ = 1/1 (molar ratio)) | 4.0 |
| Citric acid | 0.5 |
| Polyethylene glycol lauryl ether (weight | 0.7 |
| average molecular weight 1,000) | |
| PIONIN C-158-G (available from TAKEMOTO | 0.02 |
| Oil and Fats Co., Ltd.) | |
| Water | 70.0 |

[Evaluation of Printing Durability]

According to a method similar to that used for the evaluation of the developing latitude, the electrical conductance of a developer was determined, at which the image area was never dissolved out by the developer, which did not cause any contamination and/or coloration due to any insufficient development of the non-image area or any remaining film and which permitted excellent development, and the lithographic printing plate developed with the developer having such an electrical conductance was set on a printing press: LISRON Printing Press available from KOMORI Corporation and printing operations were carried out using GEOS (N) SUMI Ink available from Dainippon Ink and Chemicals, Inc. to thus determine the number of printed matters at an instance when it could visually be recognized that the density of the solid image began to be reduced and to evaluate the printing durability of the printing plate based on the number of printed matters thus determined.

As will be clear from the data listed in Table 1, the light-sensitive lithographic printing plate according to the present invention is provided with an infrared light-sensitive layer which comprises (A) a polymer represented by the general formula (I); (B) a polymeric compound carrying, on the side chains, fluorinated aliphatic groups in which the fluorinated aliphatic groups are those derived from fluorinated aliphatic compounds prepared by the telomerization or oligomerization; and (C) a light-heat conversion substance and the lithographic printing plate is excellent in the developing latitude and the lithographic printing plate prepared therefrom shows excellent printing durability (see Examples 1 to 12). In addition, the light-sensitive lithographic printing plate which further comprises the component (D) in addition to the foregoing components (A) to (C) shows an excellent effect, in particular, in the developing latitude (see the results obtained in Examples 1 to 7, 11 and 12). On the other hand, there are observed considerable reduction in the developing latitude for the light-sensitive lithographic printing plates which are free of any component (B) or the polymeric compound carrying, on the side chains, fluorinated aliphatic groups (the plates of Comparative Examples 1, 2, 5 and 6) and for the light-sensitive lithographic printing plates in which the polymeric compound containing fluorinated aliphatic groups and prepared by the electro-fluorination method is substituted for the component (B) (the plates prepared in Comparative Examples 3 and 4).

TABLE 1

| | | | | | | Printing |
|---|---|---|---|---|---|---|
| | | | | | | Durability |
| | | Component (B): | | | Developing | No. of |
| | Component (A): | F atom-containing | Component (D) | | Latitude | Printed |
| Ex. No. | Acetal polymer | polymer | Organic acid (1) | Acid anhydride | (ms/cm) | Matters |
| 1 | A | Polymer P-1 | 4,4′-Bishydroxyphenyl sulfone | Tetra-hydroxy phthalic acid anhydride | 10 | 140,000 |
| 2 | A | Polymer P-2 | 4,4′-Bishydroxyphenyl sulfone | Tetra-hydroxy phthalic acid anhydride | 10 | 140,000 |
| 3 | A | Polymer P-3 | 4,4′-Bishydroxyphenyl sulfone | Tetra-hydroxy phthalic acid anhydride | 10 | 140,000 |
| 4 | A | Polymer P-4 | None | Tetra-hydroxy phthalic acid anhydride | 9 | 150,000 |
| 5 | A | Polymer P-5 | Benzoic acid | Phthalic acid anhydride | 10 | 150,000 |
| 6 | A | MEGAFAC F-780-F¹⁾ | 4,4′-Bishydroxyphenyl sulfone | Tetra-hydroxy phthalic acid anhydride | 10 | 150,000 |
| 7 | A | Polymer P-2 | Terephthalic acid | Phthalic acid anhydride | 10 | 150,000 |
| 8 | A | Polymer P-2 | None | None | 8 | 140,000 |
| 9 | A | MEGAFAC F-780-F¹⁾ | None | None | 5 | 140,000 |
| 10 | A | MEGAFAC F-780-F²⁾ | None | None | 6 | 140,000 |
| 11 | B | MEGAFAC F-780-F²⁾ | 4,4′-Bishydroxyphenyl sulfone | Tetra-hydroxy phthalic acid anhydride | 10 | 140,000 |
| 12 | C | MEGAFAC F-780-F²⁾ | 4,4′-Bishydroxyphenyl sulfone | Tetra-hydroxy phthalic acid anhydride | 10 | 140,000 |
| 1* | A | None | 4,4′-Bishydroxyphenyl sulfone | Tetra-hydroxy phthalic acid anhydride | 2 | 140,000 |
| 2* | A | None | None | None | 0.5 | 130,000 |
| 3* | A | MEGAFAC F-177-F³⁾ | None | None | 1 | 130,000 |
| 4* | A | FC-431⁴⁾ | 4,4′-Bishydroxyphenyl sulfone | Tetra-hydroxy phthalic acid anhydride | 2 | 140,000 |
| 5* | B | None | None | None | 0.5 | 140,000 |
| 6* | C | None | None | None | 0.5 | 140,000 |

¹⁾Fluorine atom-containing polymer carrying fluoroalkyl groups prepared by the telomerization, available from Dainippon Ink and Chemicals, Inc. (content of effective component: 30%; added amount was calculated on the basis of the amount of the effective component).
²⁾Fluorine atom-containing polymer carrying fluoroalkyl groups prepared by the telomerization, available from Dainippon Ink and Chemicals, Inc.
³⁾Fluorine atom-containing polymer carrying fluoroalkyl groups prepared by the telomerization, available from Dainippon Ink and Chemicals, Inc.
⁴⁾Fluorine atom-containing polymer carrying fluoroalkyl groups prepared by the electrolytic fluorination method, available from Minnesota Mining and Manufacturing Company.

1. A light-sensitive lithographic printing plate comprising a hydrophilic substrate provided thereon with a layer sensitive to infrared light rays comprising (A) a polymer represented by the following general formula (I); (B) a polymeric compound carrying, on the side chains, a fluorinated aliphatic group which is derived from fluorinated aliphatic compound prepared by the telomerization or oligomerization; and (C) a light-heat conversion substance: 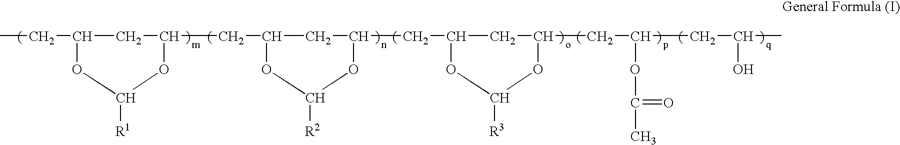
wherein, R¹ represents a group: —CₙH₂₊₁ (wherein n ranges from 1 to 12);
R² represents a group represented by the following structural formula: 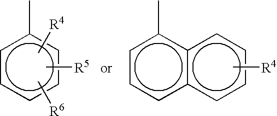
wherein, R⁴=—OH; R⁵=—H, —OH, —OCH₃, —Br, or —O—CH₂—C≡CH; R⁶=—H, —Br, or —NO₂;
R³ represents —(CH₂)ₐ—COOH, wherein a represents an integer ranging from 1 to 6, —C≡CH or the following group: 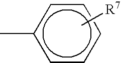
wherein R⁷=—COOH, —(CH₂)ₐ—COOH, or —O—(CH₂)ₐ—COOH);
m=5 to 40 mole %, n=10 to 60 mole %, o=0 to 20 mole %, p=1 to 10 mole %, and q=5 to 50 mole %.

2. The light-sensitive lithographic printing plate of claim 1 wherein the infrared light-sensitive layer further comprises (D) an organic acid and/or a cyclic acid anhydride.

3. The light-sensitive lithographic printing plate of claim 1 wherein component (B) comprises the following group represented by general formula (II) as the fluorinated aliphatic group: 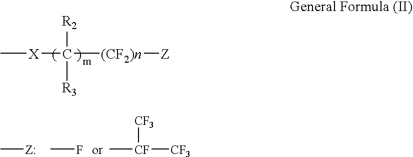
wherein, each of R₂ and R₃ independently represents a hydrogen atom or an alkyl group having 1 to 4 carbon atoms; X represents a single bond or a divalent connecting group and is connected to the main chain of the polymer; m represents 0 or an integer of not less than 1; and n is an integer of not less than 1 and not more than 10.

4. The light-sensitive lithographic printing plate of claim 1 wherein component (B) comprises the following group represented by general formula (II-1) as the fluorinated aliphatic group:
General Formula (11-1) 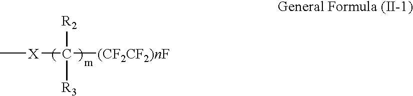
wherein, each of R₂ and R₃ independently represents a hydrogen atom or an alkyl group having 1 to 4 carbon atoms; X represents a single bond or a divalent connecting group and is connected to the main chain of the polymer; m represents 0 or an integer of not less than 1; and n is an integer of not less than 1 and not more than 10.

5. The light-sensitive lithographic printing plate of claim 1 wherein the content of (B) a polymeric compound carrying, on the side chains, a fluorinated aliphatic group in the light-sensitive layer ranges from 0.01 to 20% by weight.

6. The light-sensitive lithographic printing plate of claim 2 wherein the organic acid as component (D) has a molecular weight of not more than 500.

7. The light-sensitive lithographic printing plate of claim 6 wherein the organic acid is selected from the group consisting of sulfonic acids, sulfinic acids, alkylsulfuric acids, phosphonic acids, phosphinic acids, phosphoric acid esters, carboxylic acids, phenols, sulfonamides and sulfonimides.

8. The light-sensitive lithographic printing plate of claim 2, wherein the cyclic acid anhydrides is selected from the group consisting of phthalic acid anhydride, tetrahydro-phthalic acid anhydride, hexahydro-phthalic anhydride, 3,6-endoxy˜Δ4˜tetrahydro-phthalic acid anhydride, tetrachloro-phthalic acid anhydride, maleic acid anhydride, chloro-maleic acid anhydride, α-phenyl-maleic acid anhydride, succinic acid anhydride and pyromellitic acid anhydride.

9. The light-sensitive lithographic printing plate of claim 2, wherein the organic acids and cyclic acid anhydrides are used in any combination of at least two of them.
